(19) United States
(12) Patent Application Publication
(10) Pub. No.: US 2026/0153809 A1
(43) Pub. Date: Jun. 4, 2026

(54) SUBSTRATE PROCESSING APPARATUS AND SUBSTRATE PROCESSING METHOD

(71) Applicant: SEMES CO., LTD., Cheonan-si (KR)

(72) Inventors: Ki Hoon LIM, Bucheon-si (KR); Jun Ho KIM, Seongnam-si (KR); Byoung Doo CHOI, Cheonan-si (KR); Sung Gyu LEE, Suwon-si (KR); Ji Young CHOI, Hwaseong-si (KR); Wu Bhin CHA, Seongnam-si (KR)

(21) Appl. No.: 19/339,727

(22) Filed: Sep. 25, 2025

(30) Foreign Application Priority Data
Dec. 4, 2024 (KR) 10-2024-0178547

(51) Int. Cl. G03F 7/00; G03F 7/16; G03F 7/20

(52) U.S. Cl. CPC G03F 7/70875; G03F 7/168; G03F 7/2002; G03F 7/70725

(57) ABSTRACT

A substrate processing apparatus includes a processing chamber having a processing space, a support portion disposed within the processing space, capable of being raised and lowered and rotatable, and including a hot plate configured to support and heat a substrate, and a heating unit disposed within the processing space to be spaced apart from an upper side of the support portion, and including a lamp unit containing a plurality of lamps heating the substrate. The processing chamber includes a gas inlet portion for introducing gas into the processing space, a gas discharge portion spaced apart from the gas inlet portion and discharging the gas from the processing space, and a sealing portion disposed below the gas inlet portion or the gas discharge portion, and selectively sealing between upper and lower portions of the substrate when the substrate is seated on the support portion.

### CROSS-REFERENCE TO RELATED APPLICATION(S)

This application claims benefit of priority to Korean Patent Application No. 10-2024-0178547 filed on Dec. 4, 2024 in the Korean Intellectual Property Office, the disclosure of which is incorporated herein by reference in its entirety.

### BACKGROUND

### 1. Field

The present disclosure relates to a substrate processing apparatus and a substrate processing method.

### 2. Description of Related Art

Manufacturing semiconductor devices requires forming a certain pattern on a substrate, such as a wafer. Forming a certain pattern on a substrate may be accomplished through a series of processes, including deposition, lithography, etching, and the like.

During the lithography process, the substrate may be heat-treated in a baking chamber. At this time, a UV lamp is used to irradiate the substrate with UV light, and when the UV light interacts with the oxygen contained in the process gas within the baking chamber, ozone gas may be generated. This ozone gas may contact the substrate surface and decompose organic substances present on the substrate. However, during heat treatment on the substrate in the baking chamber, the UV light may not be uniformly irradiated onto the substrate surface, resulting in insufficient removal of organic substances.

### SUMMARY

An aspect of the present disclosure is to provide a substrate processing apparatus and a substrate processing method in which light (UV) may be uniformly irradiated to the entire surface of a substrate supplied into a baking chamber and organic substances present on the substrate surface may be effectively and uniformly removed.

According to an aspect of the present disclosure, a substrate processing apparatus includes a processing chamber having a processing space provided therein, a support portion disposed within the processing space, capable of being raised and lowered and rotatable, and including a hot plate configured to support and heat a substrate, and a heating unit disposed within the processing space to be spaced apart from an upper side of the support portion, and including a lamp unit containing a plurality of lamps configured to heat the substrate. The processing chamber includes a gas inlet portion for introducing gas into the processing space, a gas discharge portion spaced apart from the gas inlet portion and configured to discharge the gas from the processing space, and a sealing portion disposed below the gas inlet portion or the gas discharge portion, and selectively sealing between an upper portion and a lower portion of the substrate when the substrate is seated on the support portion.

According to an aspect of the present disclosure, a substrate processing method includes supplying a substrate to a processing space within a processing chamber, sealing a space between an upper portion and a lower portion of the substrate by raising a support portion, heat treating by applying heat to the substrate disposed on the support portion by a heating unit, opening the space between the upper and lower portions of the substrate by lowering the support portion, and rotating the support portion on which the substrate is supported by a preset angle.

According to an aspect of the present disclosure, a substrate processing apparatus includes a processing chamber having a processing space provided therein, a support portion disposed within the processing space, capable of being raised and lowered and rotatable, and including a hot plate configured to support and heat a substrate, and a heating unit disposed within the processing space, while being spaced apart from an upper side of the support portion, and including a lamp unit including a plurality of lamps configured to heat the substrate. The processing chamber includes a gas inlet portion disposed on one side wall of the processing chamber, and allowing gas to be introduced into the processing space therethrough, a gas discharge portion disposed on the other side wall of the processing chamber, facing the gas inlet portion, spaced apart from the gas inlet portion, and discharging the gas from the processing space therethrough, and a sealing portion disposed below the gas inlet portion or the gas discharge portion, and selectively sealing between an upper portion and a lower portion of the substrate when the substrate is seated on the support portion, The processing space includes an upper space in which the lamp unit is disposed, and a lower space which is separated from the upper space and in which the substrate is disposed and a processing process for the substrate is performed, and the lower space includes a first lower space, and a second lower space, disposed below the first lower space, and separated from or communicating with the first lower space by the sealing portion. The processing chamber further includes a partition wall portion protruding from an inner side surface of the processing chamber into the processing space toward the substrate or the support portion, and the partition wall portion is disposed to partially overlap an edge portion of the hot plate when viewed from above, and extends in a circumferential direction of the substrate supported on the hot plate. The sealing portion selectively seals between the partition wall portion and the hot plate by raising and lowering the support portion. The hot plate includes a coupling groove disposed in the edge portion, concave inwardly from an upper surface of the hot plate and extending in the circumferential direction of the hot plate. The sealing portion has a ring shape extending in the circumferential direction of the hot plate, with a lower end portion inserted into the coupling groove and an upper end portion protruding upwardly from the coupling groove and in contact with a lower surface of the partition wall portion by raising of the support portion, and selectively seals between the first lower space and the second lower space by being vertically pressurized between the hot plate and the partition wall portion. The support portion rises and the first lower space and the second lower space are sealed by the sealing portion, when the heating unit heats the substrate. The support portion is lowered and opens between the first lower space and the second lower space, when a heating process for the substrate is completed.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a top view of a substrate processing apparatus according to an embodiment;

FIG. 2 is a top view of the substrate processing apparatus of FIG. 1, taken along line A-A;

FIG. 3 is a top view of the substrate processing apparatus of FIG. 1, taken along line B-B;

FIG. 4 is a cross-sectional view schematically illustrating a substrate processing apparatus according to an embodiment;

FIG. 5A is an enlarged cross-sectional view of a portion of the substrate processing apparatus of FIG. 4;

FIG. 5B is an enlarged cross-sectional view of a portion of a substrate processing apparatus according to another embodiment;

FIG. 6 is a cross-sectional view illustrating a first state of a substrate processing apparatus according to an embodiment;

FIG. 7A is an enlarged cross-sectional view of a portion of the substrate processing apparatus of FIG. 6;

FIG. 7B is an enlarged cross-sectional view of a portion of a substrate processing apparatus according to another embodiment;

FIG. 8 is a cross-sectional view illustrating a second state of a substrate processing apparatus according to an embodiment;

FIG. 9 is a cross-sectional view illustrating a third state of a substrate processing apparatus according to an embodiment;

FIG. 10 is a cross-sectional view illustrating a fourth state of a substrate processing apparatus according to an embodiment;

FIG. 11A is a schematic top view illustrating a state in which a substrate is disposed during heat treatment;

FIG. 11B is a schematic top view illustrating a state in which the substrate of FIG. 11A is rotated at a preset angle and then heat treated;

FIG. 12 is a cross-sectional view illustrating a fifth state of a substrate processing apparatus according to an embodiment; and

FIG. 13 is a flowchart illustrating a substrate processing method according to an embodiment.

### DETAILED DESCRIPTION

Hereinafter, with reference to the attached drawings, example embodiments will be described in detail so that those skilled in the art may easily practice the present disclosure. However, in describing example embodiments in detail, if a detailed description of related known functions or configurations is determined to unnecessarily obscure the gist of the present disclosure, such detailed descriptions will be omitted. Furthermore, the same reference numerals are used throughout the drawings for parts with similar functions and actions. Furthermore, in this specification, terms such as “on,” “upper,” “upper end,” “below,” “lower,” “lower end” and the like refer to the drawings, and terms such as “inner,” “outer,” and the like refer to the outer perimeter of the corresponding component. In practice, these terms may vary depending on the orientation of the elements or components.

In addition, throughout the specification, the term “including” a component does not exclude other components, unless otherwise specified, but rather implies the inclusion of other components.

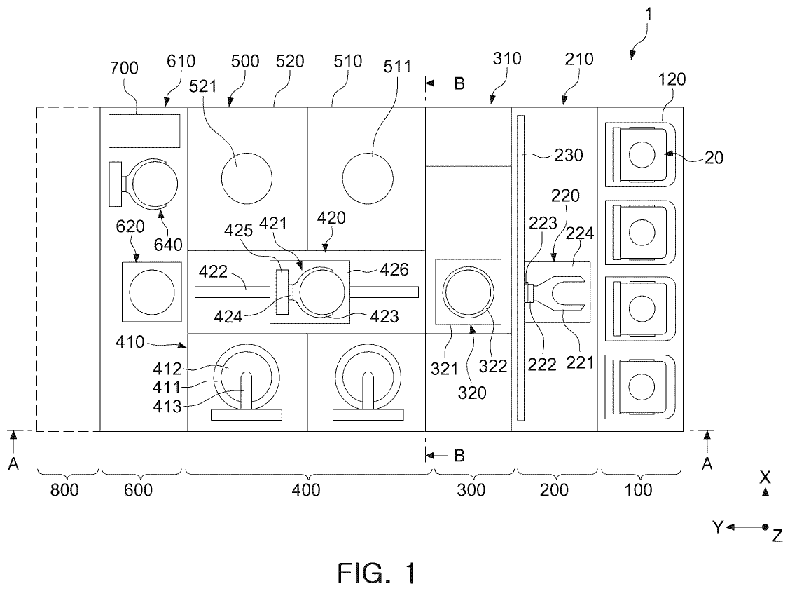

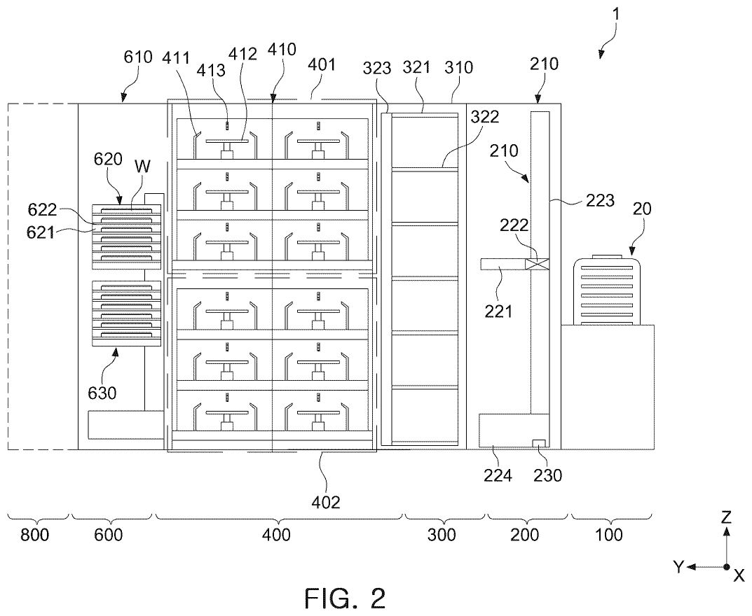

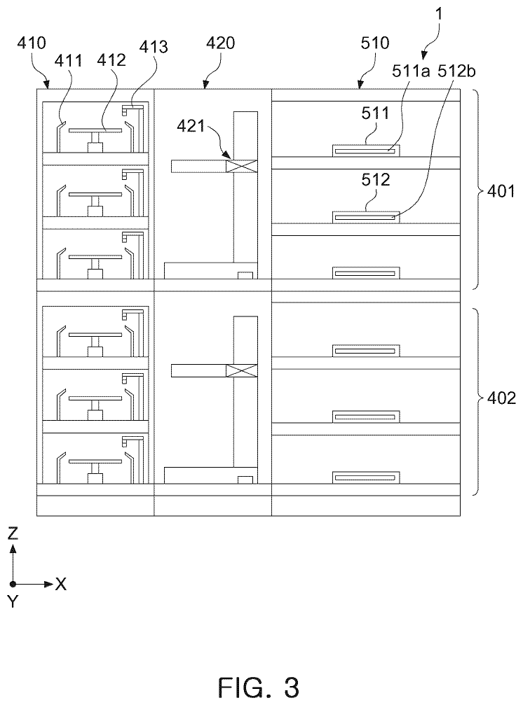

FIG. 1 is a top view of a substrate processing apparatus, FIG. 2 is a view of the substrate processing apparatus of FIG. 1 viewed from direction A-A, and FIG. 3 is a view of the substrate processing apparatus of FIG. 1 viewed from direction B-B.

Referring to FIGS. 1 to 3, a substrate processing apparatus 1 may include a load port 100, an index module 200, a buffer module 300, a coating and developing module 400, and a purge module 700. The load port 100, the index module 200, the buffer module 300, the coating and developing module 400, and the interface module 600 may be sequentially disposed in a row in one direction. The purge module 700 may be provided within the interface module 600. Alternatively, the purge module 700 may be provided at various locations, such as the location where the exposure device 800 is connected at the rear of the interface module 600 or on the side of the interface module 600. Hereinafter, the direction in which the load port 100, index module 200, buffer module 300, coating and developing module 400, and interface module 600 are disposed is referred to as the first direction (Y). The direction perpendicular to the first direction (Y) when viewed from above is referred to as the second direction (X), and the direction respectively perpendicular to both the first direction (Y) and the second direction (X) is referred to as the third direction (Z).

The substrate (W) may be transported while stored within a cassette 20. The cassette 20 may have a structure that may be sealed from the outside. For example, a Front Open Unified Pod (FOUP) with a door at the front may be used as the cassette 20.

Below, the load port 100, index module 200, buffer module 300, coating and developing module 400, interface module 600, and purge module 700 are described in detail.

The load port 100 may have a mounting plate 120 on which a cassette 20 containing a substrate (W) is placed. Multiple mounting plates 120 may be provided, and the mounting plates 120 may be disposed in a row along the second direction (X). While FIG. 1 illustrates an example in which four mounting plates 120 are provided, the number may vary.

The index module 200 may transfer the substrate (W) between the cassette 20 placed on the mounting plate 120 of the load port 100 and the buffer module 300. The index module 200 may include a frame 210, an index robot 220, and a guide rail 230.

The frame 210 is provided in the shape of a substantially rectangular parallelepiped with an interior that is hollow, and may be placed between the load port 100 and the buffer module 300. The frame 210 of the index module 200 may be provided at a lower height than a frame 310 of the buffer module 300.

The index robot 220 and the guide rail 230 may be disposed within the frame 210. The index robot 220 may be provided such that a hand 221 for directly handling a substrate (W) may move and rotate in a first direction (Y), a second direction (X), and a third direction (Z). The index robot 220 may include a hand 221, an arm 222, a support 223, and a pedestal 224. The hand 221 may be fixedly installed on the arm 222. The arm 222 may be provided with a flexible structure and a rotatable structure. The support 223 may be disposed such that the longitudinal direction thereof is in the third direction (Z). The arm 222 may be coupled to the support 223 to be movable along the support 223. The support 223 may be fixedly coupled to the pedestal 224. The guide rail 230 may be provided such that the longitudinal direction thereof is disposed in the second direction (X). The pedestal 224 may be coupled to the guide rail 230 to be linearly movable along the guide rail 230. In addition, although not illustrated, the frame 210 may further include a door opener for opening and closing the door of the cassette 20.

The buffer module 300 may include a frame 310, a first buffer 320, a second buffer 330, and a cooling chamber 340. The frame 310 is provided in the shape of a rectangular parallelepiped with an interior that is hollow, and may be disposed between the index module 200 and the coating and developing module 400. The first buffer 320, the second buffer 330, and the cooling chamber 340 may be positioned within the frame 310. The cooling chamber 340, the second buffer 330, and the first buffer 320 may be sequentially disposed from below along the third direction (Z). The first buffer 320 may be positioned at a height corresponding to a coating module 401 of the coating and developing module 400, and the second buffer 330 and the cooling chamber 340 may be provided at a height corresponding to a development module 402 of the coating and developing module 400.

The first buffer 320 and the second buffer 330 may each temporarily store a plurality of substrates (W). The first buffer 320 may have a housing 321 and a plurality of supports 322. In the first buffer 320, the supports 322 are disposed within the housing 321 and may be provided to be spaced apart from each other along a third direction (Z). The second buffer 330 may have a housing 331 and a plurality of supports 332. In the second buffer 330, the supports 332 are disposed within the housing 331 and may be provided to be spaced apart from each other along a third direction (Z). One substrate (W) may be disposed on each support 322 of the first buffer 320 and each support 332 of the second buffer 330. The housing 331 may have an opening in the direction in which the index robot 220 is provided, allowing the index robot 220 to load or unload a substrate (W) onto the support 332 within the housing 331.

The first buffer 320 has a structure generally similar to that of the second buffer 330. However, the housing 321 of the first buffer 320 may have an opening in the direction in which the first buffer robot 360 is provided and in the direction in which an application robot 421 located in the coating module 401 is provided. The number of supports 322 provided in the first buffer 320 and the number of supports 332 provided in the second buffer 330 may be the same or different. In one example, the number of supports 332 provided in the second buffer 330 may be greater than the number of supports 322 provided in the first buffer 320.

The cooling chamber 340 may cool each substrate (W). The cooling chamber 340 may include a housing 341 and a cooling plate 342. The cooling plate 342 may have an upper surface on which the substrate (W) is placed, and a cooling unit 343 for cooling the substrate (W). Various methods, such as cooling using cooling water or cooling using a thermoelectric element, may be used as the cooling unit 343. In addition, the cooling chamber 340 may be provided with a lift pin assembly for positioning the substrate (W) on the cooling plate 342. The housing 341 may have openings in the direction in which the index robot 220 is provided and in the direction in which the developing robot is provided so that the index robot 220 and the developing robot provided in the development module 402 may load or unload the substrate (W) onto or from the cooling plate 342. In addition, the cooling chamber 340 may be provided with doors for opening and closing the above-described openings.

Although the buffer module 300 has been described above as an embodiment including the configurations of the cooling chamber 340, the present disclosure is not limited thereto, and the cooling chamber 340 may be omitted as needed.

The coating module 401 may include a process for applying a photosensitive solution, such as photoresist, to a substrate (W), and a heat treatment process, such as heating and cooling, for the substrate (W) before and after the resist application process. The coating module 401 may include a coating chamber 410, a heat treatment chamber section 500, and a return chamber 420. The coating chamber 410, the return chamber 420, and the heat treatment chamber section 500 may be sequentially disposed along the second direction (X). For example, with respect to the return chamber 420, a coating chamber 410 may be provided on one side of the return chamber 420, and a heat treatment chamber section 500 may be provided on the other side of the return chamber 420.

The coating chamber 410 may be provided as a plurality of coating chambers, and respectively provided in plural in the third direction (Z). Furthermore, as illustrated in FIG. 1, a plurality of coating chambers 410 may be provided in the first direction (Y), or a single coating chamber 410 may be provided in the first direction (Y).

The heat treatment chamber section 500 includes a baking chamber 510 and a cooling chamber 520, and the baking chamber 510 and the cooling chamber 520 may be each provided in plural in the third direction (Z). The return chamber 420 may be positioned parallel to the first buffer 320 of the first buffer module 300 in the first direction (Y). The application robot 421 and a guide rail 422 may be positioned within the return chamber 420. The return chamber 420 may have a generally rectangular shape. The application robot 421 may transfer a substrate (W) between the baking chamber 510, the cooling chamber 520, the coating chamber 410, and the first buffer 320 of the first buffer module 300.

The guide rail 422 may be disposed so that the longitudinal direction thereof is parallel to the first direction (Y). The guide rail 422 may guide the application robot 421 to move linearly in the first direction (Y). The application robot 421 may have a hand 423, an arm 424, a support 425, and a pedestal 426. The hand 423 may be fixedly installed to the arm 424. The arm 424 may be provided with an elastic structure so that the hand 423 may move horizontally. The support 425 may be provided so that the longitudinal direction thereof is disposed in the third direction (Z). The arm 424 may be coupled to the support 425 to be linearly moved in the third direction (Z) along the support 425. The support 425 is fixedly connected to the pedestal 426, and the pedestal 426 may be connected to the guide rail 422 to be movable along the guide rail 422.

The coating chambers 410 may all have the same structure, but the types of treatment solution used in respective coating chambers 410 may differ from each other. The treatment solution may be a treatment solution for forming a photoresist film or an anti-reflection film.

The coating chamber 410 may apply the treatment solution onto a substrate (W). In the coating chamber 410, a treatment unit including a treatment container 411, a support portion 412, and a nozzle portion 413 may be provided.

For example, the coating chamber 410 has one treatment unit disposed along the first direction (Y). However, this arrangement is not limited thereto, and two or more treatment units may be disposed in a single coating chamber 410. Respective treatment units may have the same structure. However, the types of treatment solution used in respective treatment units may differ from each other. The treatment container 411 of the coating chamber 410 may have an open top. The support portion 412 is positioned within the treatment container 411 and may support the substrate (W). The support portion 412 may be provided to be rotatable. The nozzle portion 413 may supply the treatment solution onto the substrate (W) disposed on the support portion 412. The treatment solution may be applied to the substrate (W) using a spin coat method. In addition, the coating chamber 410 may optionally further include a nozzle (not illustrated) for supplying a cleaning solution, such as deionized water (DIW), to clean the surface of the substrate (W) to which the treatment solution has been applied, and a back rinse nozzle (not illustrated) for cleaning the lower surface of the substrate (W).

In the baking chamber 510, the substrate (W) may be heat-treated when the wafer (W) is mounted thereon by the application robot 421. In the baking chamber 510, a prebake process may be performed to remove organic substances or moisture from the surface of the substrate (W) by heating the substrate (W) to a predetermined temperature before applying the treatment solution, or a soft bake process may be performed after applying the treatment solution onto the wafer (W). After each heating process, a cooling process and the like may be performed to cool the substrate (W).

The baking chamber 510 may include a hot plate 511 and a heating unit 511a.

The heating unit 511a may heat the substrate (W) disposed inside the baking chamber 510. At this time, the substrate (W) is heated while the baking chamber 510 is sealed, and the heating unit 511a may heat the entire area of the substrate (W) to a uniform temperature. For example, the heating unit 511a may utilize a heating method utilizing heating wires installed on the interior of or the exterior surface of the hot plate 511.

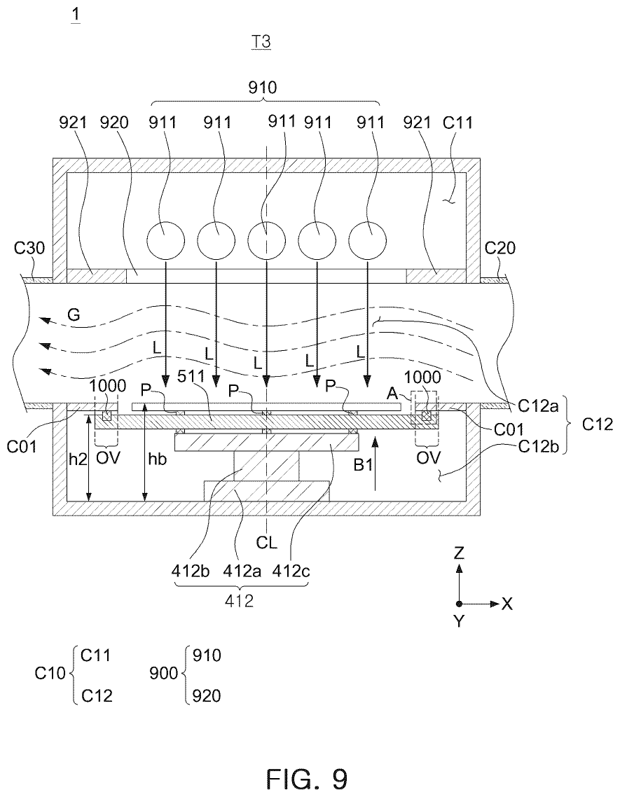

Also, a heating method utilizing a device such as a heater disposed inside or outside the baking chamber 510 may be utilized. For example, the baking chamber 510 may be equipped with a lamp unit 910 that irradiates light, such as ultraviolet rays (see L in FIG. 9), onto the upper surface of the substrate (W) to heat-treat the substrate (W).

The heat treatment process described above may stabilize the liquid film formed by blowing organic substances onto the liquid film formed by applying the treatment solution to the substrate (W).

Furthermore, the baking chamber 510 may further be equipped with a chill plate (not illustrated). The chill plate may receive cooling water from the cooling unit 910, described below, to cool the substrate (W). This prevents the substrate (W) from being heated to excessively high temperatures during the heat treatment process. The substrate (W) that has undergone the heat treatment process may be transported to a cooling chamber 520.

In the cooling chamber 520, a cooling process is performed to cool the substrate (W) before applying the treatment solution. The cooling chamber 520 may be equipped with a cooling plate. The cooling plate may include a cooling unit that may utilize various methods, such as cooling with coolant or cooling using a thermoelectric element, to cool the substrate (W).

The interface module 600 may connect the coating and developing module 400 to an external exposure device 800. The interface module 600 includes an interface frame 610, a first interface buffer 620, a second interface buffer 630, and a transfer robot 640. The transfer robot 640 may transfer substrates returned to the first and second interface buffers 620 and 630 after the coating and developing module 400 has completed processing, to the exposure device 800. The first and second interface buffers 620 include a housing 621 and a support 622, and the transfer robot 640 and the application robot 421 may load and unload substrates (W) onto and from the support 622.

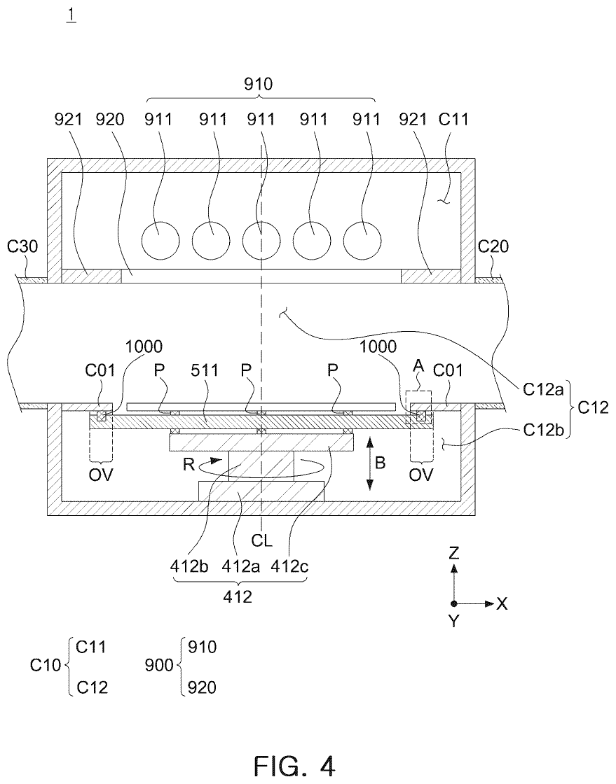

FIG. 4 is a cross-sectional view schematically illustrating a substrate processing apparatus according to an embodiment.

Referring to FIG. 4, a substrate processing apparatus 1 may include a processing chamber (C), a support portion 412, a heating unit 900, and a sealing portion 1000. Since the features of other components of the substrate processing apparatus 1 are the same or similar to those described above, their repeated description will be omitted.

The processing chamber (C) may have a processing space C10 provided therein. A substrate (W) may be supplied to the processing space C10, and a processing process may be performed on the substrate (W). In more detail, a heat treatment process may be performed on the substrate (W) in the processing space C10. In this case, the processing chamber (C) may be a baking chamber 510.

The processing chamber (C) may include a gas inlet portion C20 and a gas discharge portion C30. The gas inlet portion C20 is connected to an external gas supply device (not illustrated) and may supply gas into the processing space C10.

The gas supplied through the gas inlet portion C20 is a process gas for decomposing organic matter present on the surface of the substrate (W) and may contain oxygen (O₂). After this gas is supplied to the processing space C10, the oxygen contained in the gas may interact with light (L) emitted from the lamp 911 to generate ozone (O₃). The ozone (O₃) thus generated may decompose the organic film (organic matter) present on the substrate (W).

The gas discharge portion C30 may discharge gas within the processing space C10. The gas discharged through the gas discharge portion C30 may contain byproducts generated during the decomposition of organic matter, as described above, and/or foreign substances such as dust present within the processing space C10.

The gas inlet portion C20 may be positioned at various locations within the processing chamber (C). At this time, the gas discharge portion C30 may be positioned spaced apart from the gas inlet portion C20. In an embodiment, the gas inlet portion C20 may be positioned in one sidewall of the processing chamber (C). In this case, the gas discharge portion C30 may be positioned in the other sidewall of the processing chamber (C). Accordingly, the gas inlet portion C20 and the gas discharge portion C30 may be positioned opposite each other in the width direction (X) of the processing chamber (C). However, the present disclosure is not limited thereto.

The support portion 412 may be positioned within the processing space C10. A substrate (W) supplied into the processing space C10 may be supported and secured on the support portion 412.

A plate may be positioned on the top of the support portion 412. The plate supports the substrate (W) and may be a hot plate as described above. Hereinafter, the plate will be referred to as a hot plate 511. As described above, the hot plate 511 may include a heating unit 511a for heating the substrate (W).

The hot plate 511 may include a plurality of support pins (P). The support pins (P) may protrude upward (+Z) from the upper surface of the hot plate 511. The lower surface of the substrate (W) may be supported by these multiple support pins (P).

The multiple support pins (P) may be provided to be movable upward and downward from the hot plate 511. In more detail, the hot plate 511 may be provided with a plurality of through holes that are formed vertically (Z) by penetrating through the hot plate 511. The multiple support pins (P) may be slidably inserted into the respective through holes. In this case, when a new substrate (W) is supplied to the support portion 412 or a heat-treated substrate (W) is discharged, the multiple support pins (P) may be raised while inserted into the through-holes. In this state, the substrate (W) may be transported onto the support pins (P) by the application robot 421.

Thereafter, the multiple support pins (P) are lowered again, allowing the new substrate (W) to settle on the hot plate 511, thereby completing the substrate supply process. As another example, after the heat treatment is completed, the substrate (W) may be transported upwards above the hot plate 511 by the elevation of the multiple support portions (P). In this state, the heat-treated substrate (W) may be gripped by the application robot 421 and discharged from the processing chamber (C).

The support portion 412 may include a drive motor 412a and a driving shaft 412b. In addition, the support portion 412 may further include a support plate 412c. The lower end portion of the driving shaft 412b may be connected to the drive motor 412a. In addition, a support plate 412c may be disposed on the upper end portion of the driving shaft 412b. At this time, a plurality of support pins (P) described above may be installed to be able to rise and fall on the upper end portion of the support plate 412c. In addition, a hot plate 511 may be disposed on the upper portion of the support plate 412c.

In this case, when the drive motor 412a provides power to the driving shaft 412b, the driving shaft 412b may be raised or lowered in the vertical direction (Z). This allows the support plate 412c and hot plate 511 to also be raised and lowered. Furthermore, the drive motor 412a may provide the power necessary for the multiple support pins (P) to be raised and lowered.

The heating unit 900 may perform heat treatment on a substrate (W) disposed within the processing space C10. In this case, the heating unit 900 may include a lamp unit 910 and a window 920. The lamp unit 910 is configured to heat the substrate (W) and may include multiple lamps (L). For example, the lamp 911 may be a light source, such as a UV lamp, and may irradiate light (L) for heat-treating the substrate (W). In this case, the light (L) may be ultraviolet light with a wavelength of 10 to 300 nm.

The heating unit 900 may be positioned in the upper end portion of the processing space C10. In more detail, the processing space C10 may include an upper space C11 and a lower space C12. The upper space C11 and the lower space C12 are separate spaces, and the window 920 may be positioned between the upper space C11 and the lower space C12. The heating unit 900 may be positioned within the upper space C11 of these separated upper/lower spaces C11 and C12.

The lower space C12 may be divided into a first lower space C12a, which is the upper region of the substrate (W), and a second lower space C12b, which is the lower region of the substrate (W), based on the wafer (W) (or the upper surface of the substrate (W)) supported on the support portion 412. In this case, a hot plate 511 and a partition wall portion C01 may be positioned between the first lower space C12a and the second lower space C12b.

In more detail, the hot plate 511 may be positioned at the center of the processing space C10, between the first lower space C12a and the second lower space C12b. In this case, the center may be a region that includes an imaginary center extending along the height direction (Z) and passing through the center (C) of the processing space C10.

The partition wall portion C01 may be positioned between the first lower space C12a and the second lower space C12b, with one end (the first end) connected to the inner side surface of the processing space C10, and the other end (the second end) extending toward the edge portion of the hot plate 511. Furthermore, the partition wall portion C01 may extend to surround the hot plate 511 when viewed from above (for example, in the X-Y plane).

In this case, the second end of the partition wall portion C01 may partially overlap the edge portion of the hot plate 511 when viewed from above (in the X-Y plane). The region where the partition wall portion C01 and the hot plate 511 overlap is referred to as the “overlapping region (OV).”

In the overlapping region (OV), a portion (for example, the second end) of the partition wall portion C01 and the edge portion of the hot plate 511 may be disposed together. At this time, a portion of the partition wall portion C01 and the edge portion of the hot plate 511 are spaced apart by a predetermined distance in the vertical direction (Z), thereby forming a “separation space” between the partition wall portion C01 and the edge portion of the hot plate 511. A sealing portion 1000 is disposed in this separation space, which will be described later.

Meanwhile, the second end of the partition wall portion C01 may be spaced apart by a predetermined distance from the edge portion of the substrate (W) supported on the hot plate 511. This prevents contact between the substrate (W) and the partition wall portion C01, thereby preventing the generation of foreign matter due to friction between the substrate (W) and the partition wall portion C01.

The gas supply portion C20 and the gas discharge portion C30 may be positioned above the partition wall portion C10 and the second lower space C12b. For example, the lower end portions of the gas supply portion C20 and the gas discharge portion C30 may be positioned flush with the upper surface of the partition wall portion C01. In this case, when the substrate (W) is supported on the support portion 412, the upper surface of the substrate (W) may be at the same or a similar height as the upper surface of the partition wall portion C01. Accordingly, during heat treatment of the substrate (W), the gas (process gas) supplied to the gas inlet portion C20 may contact the upper surface of the substrate (W) while passing through the first lower space C12a and moving to the gas discharge portion C30.

In addition, the separation space between the above-described partition wall portion C01 and the edge portion of the hot plate 511 is sealed by the sealing portion 1000, whereby the gas may pass only through the first lower space C12a and then be discharged to the outside without flowing into the second lower space C12b.

The lamp unit 910 may be disposed in the upper space C11. Multiple lamps 911 may be spaced apart at predetermined intervals along the width direction (X) within the upper space C11. The multiple lamps 911 may be disposed to extend parallel to each other. For example, the extension direction (Y) of the lamps 911 may be parallel to the upper surface of the substrate (W) and perpendicular to the width direction (X).

The window 920 may be disposed below the lamp unit 910. The window 920 may extend to a length equal to or longer than the lamp unit 910. For example, the window 920 may be formed of quartz.

The window 920 may be supported by a support 921 disposed to surround the outside of the window 920 along the circumferential direction when viewed from above (in the XY plane). With the window 920 supported in this manner, the support 921 may be fixedly installed within the processing space C10. The upper space C11 and the lower space C12 may be separated by the window 920 and the support 921 surrounding and supporting the same.

The substrate (W) may be disposed in the lower space C12. In more detail, the support portion 412 may be disposed below the window 920 within the lower space C1. For example, the support portion 412 may be disposed to share a virtual centerline (CL) with the window 920. A substrate (W) to be heat treated may be supported on the support portion 412 disposed in this manner.

In the above case, light (ultraviolet rays) (L) emitted from multiple lamps 911 may pass through a transparent window 920 and enter the first lower space C12a. In the first lower space C12a, oxygen contained in the gas (process gas) may interact with the light (L) to generate ozone. The ozone thus generated may decompose the organic film (organic matter) present on the surface of the substrate (W) and remove the same from the substrate (W). Additionally, some of the light (L) traveling to the first lower space C12a may be irradiated onto the surface of the substrate (W) and directly decompose some of the organic film (organic matter).

During the decomposition of the organic film (organic matter) as described above, various types of byproducts may be generated within the first lower space C12a. Byproducts may include, for example, CO₂, H₂0, or the like. These byproducts are discharged outside the processing space C10 by an airflow (G) formed from the gas inlet portion C20 toward the gas discharge portion C30, which will be described later.

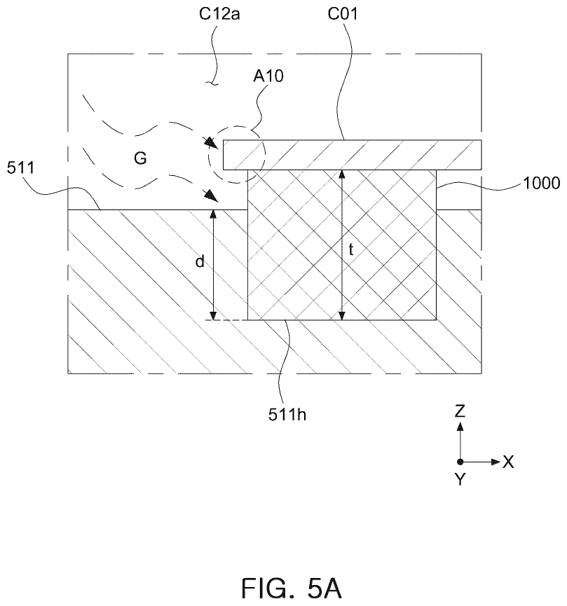

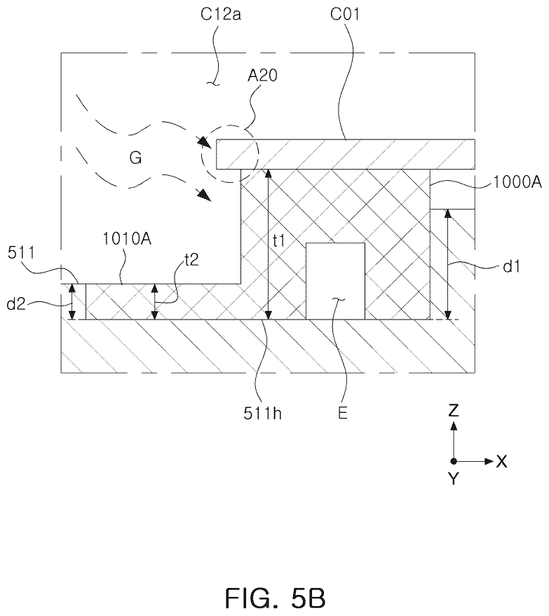

FIG. 5A is an enlarged cross-sectional view of a portion of the substrate processing apparatus of FIG. 4.

Referring to FIGS. 4 and 5A, the sealing portion 1000 may selectively seal the upper and lower portions of a substrate (W) supported on the support portion 412. In more detail, the sealing portion 1000 may seal the space between the first lower space C12a and the second lower space C12b.

The sealing portion 1000 may be positioned below the gas inlet portion C20 and/or the gas discharge portion C30. The sealing portion 1000 may be positioned between the partition wall portion C01 and the hot plate 511.

For example, the sealing portion 1000 may be positioned on the hot plate 511. The sealing portion 1000 may be positioned on the edge portion of the hot plate 511 within the overlapping region (OV) described above. At this time, the sealing portion 1000 may have a ring shape extending in the circumferential direction of the hot plate 511 such that both ends meet.

In this case, the hot plate 511 may include a coupling groove 511h. The coupling groove 511h is a portion into which the sealing portion 1000 is inserted and coupled, and may be positioned on the edge portion of the hot plate within the overlapping region (OV). The coupling groove 511h may be formed concavely in the inward direction (−Z) on the upper surface, which is the surface facing the partition wall portion C01. At this time, the coupling groove 511h may have a shape corresponding to the sealing portion 1000. In more detail, when the sealing portion 1000 is ring-shaped, the coupling groove 511h may have a diameter equal to or similar to that of the sealing portion 1000 and may be a ring-shaped groove extending in the circumferential direction of the hot plate 511.

Based on the vertical direction (Z), the depth (d) of the coupling groove 511h may be smaller than the thickness (t) of the sealing portion 1000. Accordingly, when the sealing portion 1000 is inserted into the coupling groove 511h, the lower end portion of the sealing portion 1000 may be inserted into the coupling groove 511h, while the upper end portion of the sealing portion 1000 may protrude upwardly of the coupling groove 511h.

Furthermore, referring to area A10 illustrated in FIG. 5A, the partition wall portion C01 may protrude further toward the center (CL) of the processing space C10 than the sealing portion 1000. In this case, the support portion 412 may be raised, allowing the sealing portion 1000 to more stably adhere to the lower surface of the partition wall portion C01. Consequently, the sealing stability between the upper and lower portions of the substrate (W) (for example, between the first lower space C12a and the second lower space C12b) may be improved.

The sealing portion 1000 may be detachably connected to the coupling groove 511h. For example, the sealing portion 1000 may include a connecting hole (not illustrated) formed vertically (Z). A connecting member (not illustrated), such as a bolt, may be inserted into this connecting hole and screwed into a threaded portion (not illustrated) on the bottom surface of the coupling groove 511h. In this way, the sealing portion 1000 may be detachably connected to the coupling groove 511h, enabling easy replacement of the sealing portion 1000.

When the sealing portion 1000 is tightly secured to the lower surface of the partition wall portion C01, the first lower space C12a and the second lower space C12b are sealed and separated, thereby preventing gas (G) within the first lower space C12a from flowing into the second lower space C12b. To this end, the sealing portion 1000 may be formed of a material that is highly resistant to ozone (O₃) contained in the above-described gas (G) and/or ultraviolet light (L). For example, the sealing portion 1000 may be formed of Polytetrafluoroethylene (PTFE) material.

FIG. 5B is an enlarged cross-sectional view illustrating a portion of a substrate processing apparatus according to another embodiment.

Referring to FIG. 5B, a sealing portion 1000A according to another embodiment may selectively seal the upper and lower portions of a substrate (W) supported on a support portion 412. At this time, the sealing portion 1000A is positioned between the partition wall portion C01 and the hot plate 511, thereby sealing the space between the first lower space C12a and the second lower space C12b, as in the aforementioned embodiment.

For example, the sealing portion 1000A may be positioned on the hot plate 511. The sealing portion 1000A may be positioned on the edge portion of the hot plate 511 within the overlapping region (OV) described above. At this time, the sealing portion 1000A may extend along the circumference of the hot plate 511 and have a ring shape with both ends meeting. At this time, the sealing portion 1000 may be provided with an inner groove (E), which is an empty space.

The inner groove (E) may be formed concavely upward (+Z) on the lower surface of the sealing portion 1000. When the sealing portion 1000 is raised by the support portion 412 and comes into contact with the partition wall portion C01, the sealing portion 1000 may undergo a certain deformation due to vertical pressure. At this time, the sealing portion 1000 has a free space formed inside by the inner groove (E), thereby ensuring flexibility in deformation when the sealing portion 1000 is vertically pressed, as described above.

Additionally, the sealing portion 1000A may further include an extension portion 1010A. The extension portion 1010A may be positioned at the lower end of the sealing portion 1000A. The extension portion 1010A may have a shape that protrudes radially inward from the lower end of the sealing portion 1000A toward the center of the hot plate 511 or the center (CL) of the processing space C10. Furthermore, the extension portion 1010A may extend along the circumference of the hot plate 511 and be provided in a ring shape with both ends meeting each other.

The hot plate 511 may include a coupling groove 511h. The coupling groove 511h may be positioned at the edge portion of the hot plate within the overlapping region (OV). The coupling groove 511h may be formed concavely inwardly (−Z) on the upper surface, which is the surface facing the partition wall portion C01.

At this time, the coupling groove 511h may have a shape corresponding to the sealing portion 1000A. In more detail, if the sealing portion 1000A is a ring-shaped portion including an extension portion 1010A at the lower end thereof, the coupling groove 511h may have a diameter identical or similar to that of the sealing portion 1000A including the extension portion 1010A, and may be provided in the form of a ring-shaped groove extending along the circumference of the hot plate 511.

The lower end portion and the extension portion 1010A of the sealing portion 1000A may be inserted into the coupling groove 511h. At this time, the thickness t2 of the extension portion 1010A may be smaller than the thickness t1 of the sealing portion 1000A. At this time, the thickness t1 of the sealing portion 1000A may be greater than the radially outer depth d1 of the coupling groove 511h. Furthermore, the thickness t2 of the extension portion 1010A may be equal to the radially inner depth d2 of the coupling groove 511h. Accordingly, the sealing portion 1000A may be positioned so that the upper end thereof protrudes upwardly of the coupling groove 511h, while the extension portion 1010A remains inserted within the coupling groove 511h.

In this way, by including the extension portion 1010A in the sealing portion 1000A, the area supported by the sealing portion 1000 within the coupling groove 511h may be increased. Additionally, when the sealing portion 1000 comes into contact with the lower surface of the partition wall portion C01 due to the elevation of the support portion 412, the pressure applied in the vertical direction (Z) may be distributed to the lower end portion and the extension portion 1010A of the sealing portion 1000. Consequently, the sealing portion 1000 may be stably supported and fixed within the coupling groove 511h.

Furthermore, referring to area A20 illustrated in FIG. 5B, the partition wall portion C01 may protrude further toward the center (CL) of the processing space C10 than the sealing portion 1000. In this case, as described above, the support portion 412 is raised so that the sealing portion 1000 may be more securely attached to the lower surface of the partition wall portion C01, and as a result, the sealing stability between the upper and lower portions of the substrate (W) (for example, between the first lower space C12a and the second lower space C12b) may be improved. This sealing portion 1000 may be manufactured from Polytetrafluoroethylene (PTFE) which has strong resistance to ultraviolet rays and ozone.

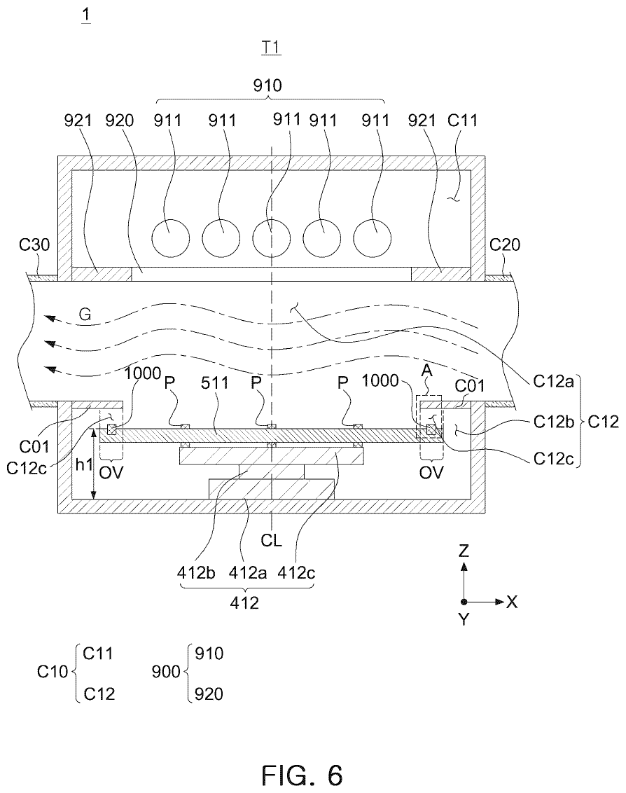

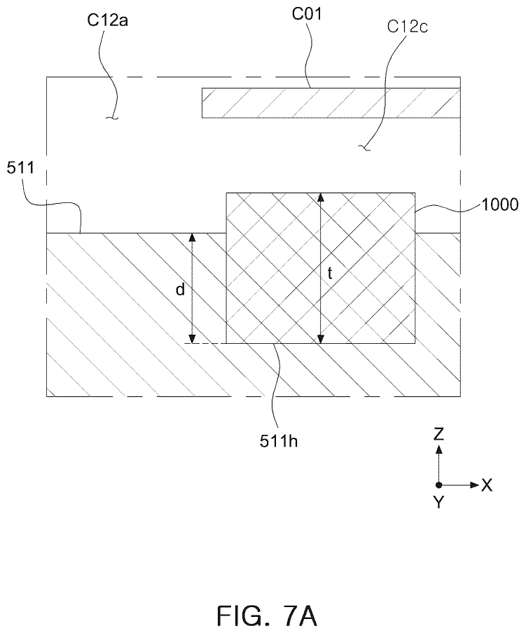

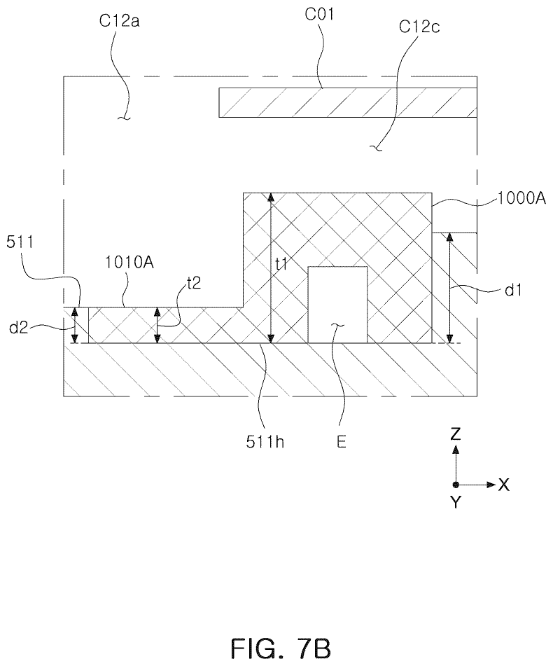

FIG. 6 is a cross-sectional view illustrating a first state of a substrate processing apparatus according to an embodiment. FIG. 7A is an enlarged cross-sectional view of a portion of the substrate processing apparatus of FIG. 6. FIG. 7B is an enlarged cross-sectional view of a portion of a substrate processing apparatus according to another embodiment.

Referring to FIGS. 6 and 7A, in the state before a substrate is supplied to the substrate processing apparatus 1 (hereinafter, referred to as the first state) T1, the support portion 412 may be lowered downwardly, to be lower than the “processing position.” In this case, the processing position may be a position where the upper end of the sealing portion 1000 is raised so that it is in close contact with the lower surface of the partition wall portion C01, as illustrated in FIG. 4. For example, at the processing position, the upper surface of the substrate (W) supported on the support portion 412 may be located on the same plane as the lower end portion of the gas inlet portion C20 and the gas discharge portion C30, and/or the upper surface of the partition wall portion C01.

When the substrate processing apparatus 1 is in the first state T1, it may be before the substrate (W) is supplied onto the hot plate 511. At this time, since the support portion 412 is lowered downwardly to be lower than the processing position, the hot plate 511 may be positioned at a predetermined height (hereinafter, referred to as the first height) h1 spaced apart from the partition wall portion C01.

When the hot plate 511 is positioned at the first height h1, the edge portion of the hot plate 511 and the sealing portion 1000 positioned thereon may be spaced apart from the lower surface of the partition wall portion C01. In this case, the space between the partition wall portion C01 and the hot plate 511 (or between the partition wall portion C01 and the sealing portion 1000) may be opened. As a result, a “passage portion C12c” formed by the partition wall portion C01 and the hot plate 511 (or between the partition wall portion C01 and the sealing portion 1000 may be formed in the overlapping region (OV) and vertically partitioned. The first lower space C12a and the second lower space C12b may be connected to each other by the passage portion C12c.

Referring to FIG. 7B, in the case of the sealing portion 1000A according to another embodiment, the support portion 412 may also be lowered toward the lower side (−Z) of the processing position and positioned when the substrate processing apparatus 1 is in the first state T1. Accordingly, in the overlapping region (OV), the passage portion C12c, which is a space in which the sealing portion 1000A and the partition wall portion C01 are spaced apart from each other, in the same manner as or similar to the above-described embodiment.

In the first state T1 described above, the lamp unit 910 may be kept in the off state with the lamp 911 not emitting light (L). However, gas (G) may be supplied through the gas inlet portion C20.

For example, when the substrate processing apparatus 1 is in the first state T1, gas may be continuously supplied through the gas inlet portion C20. The supplied gas passes through the lower space C12 of the processing space C10 and is discharged to the gas discharge portion C30, thereby forming an air current in which the gas (G) flows in the width direction (X) within the first lower space C12a. By the airflow formed in this manner, contaminants present within the processing space C10 may be discharged and removed before the substrate (W) is supplied to the processing chamber (C).

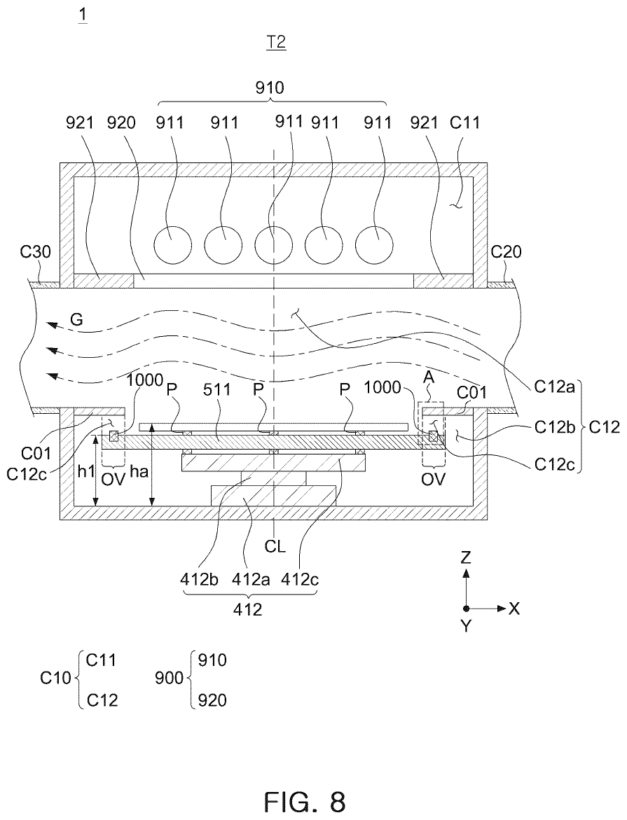

FIG. 8 is a cross-sectional view illustrating a second state of a substrate processing apparatus according to an embodiment.

Referring to FIG. 8, a substrate (W) may be supplied to the substrate processing apparatus 1 in the first state T1. The substrate (W) may be transported to the support portion 412 within the lower space C12. During this process, the substrate (W) may be transported, for example, by an application robot 421. The substrate (W) may be disposed on a hot plate 511. At this time, the substrate (W) may be disposed with the lower surface thereof supported by a plurality of support pins (P).

When the substrate processing apparatus 1 is in the second state T2, the support portion 412 remains lowered further than the processing position, and the hot plate 511 may maintain the first height h1 of the first state T1. At this time, the substrate (W) supported on the hot plate 511 may be positioned at a height (hereinafter, “initial height”) (ha) at which the upper surface thereof is positioned to be lower than the gas inlet portion C20 and/or the gas discharge portion C30.

In this way, the state in which the substrate (W) is supplied to the substrate processing apparatus 1 in the first state T1 and is seated and supported on the hot plate 511 is defined as the “second state T2.” In the second state T2, the space between the partition wall portion C01 and the sealing portion 1000 or the hot plate 511 is opened, allowing the passage portion C12c to be maintained.

FIG. 9 is a cross-sectional view illustrating a third state of a substrate processing apparatus according to an embodiment.

Referring to FIG. 9, when the supply of the substrate (W) is completed in the second state T2, the support portion 412 may rise along the first transport direction B1. Simultaneously, the hot plate 511 and the sealing portion 1000 may also rise along the first transport direction B1 to the aforementioned “processing position.”

Upon reaching the processing position, the sealing portion 1000 may have the upper end portion thereof pressed against the lower surface of the partition wall portion C01. Consequently, the space between the upper and lower portions of the substrate (W) (for example, between the first lower space C12a and the second lower space C12b) is sealed, thereby preventing gas flowing into the first lower space C12a from flowing into the second lower space C12b. In this way, the state in which the substrate (W) is supported on the hot plate 511, the first lower space C12a and the second lower space C12b are sealed and separated from each other, and the passage portion C12c is closed is defined as the ‘third state T3’.

When the substrate processing apparatus 1 is in the third state T3, as the support portion 412 rises to the processing position, the substrate (W) may be disposed at the ‘processing height (hb)’, which is a height at which heat treatment is performed, higher than the aforementioned initial height (ha). When the processing height (hb) is reached, the upper surface of the substrate (W) may be disposed at the same or similar height as the lower end of the gas inlet portion C20 and/or the gas discharge portion C30. In addition, when the third state T3 is reached, the height of the hot plate 511 may also be disposed at the ‘second height h2’, which is higher than the aforementioned first height h1.

In the third state T3 described above, the heating unit 900 may perform heat treatment on the substrate (W). In more detail, when the space between the first lower space C12a and the second lower space C12b is completely sealed, multiple lamps 911 may emit light (L) toward the substrate (W).

The emitted light (L) may pass through the window 920 and enter the first lower space C12a. Thereafter, while passing through the airflow formed within the first lower space C12a, the light (L) reacts with oxygen contained in the gas (G), thereby generating ozone gas. The ozone gas thus generated travels along the airflow within the first lower space C12a, contacts the upper surface of the substrate (W), and undergoes a decomposition reaction with the organic film (organic matter) present on the surface (upper surface) of the substrate (W). By this, the organic film (organic matter) may be decomposed and removed from the upper surface of the substrate (W). Furthermore, reaction products (for example, CO₂, H₂O) generated by the organic matter decomposition reaction may be transported by the airflow and discharged through the gas discharge portion C30.

The heat treatment process for the substrate (W) described above may be performed while the space between the first lower space C12a and the second lower space C12b is completely and continuously sealed. This prevents the gas (process gas) supplied to the first lower space C12a, ozone gas generated by light (L), and/or reaction products resulting from the organic matter decomposition reaction from flowing into the second lower space C12b where the support portion 412 is positioned during the heat treatment process. This has the effect of preventing the support portion 412, including the drive motor 412a, from being damaged by ozone gas, or the like.

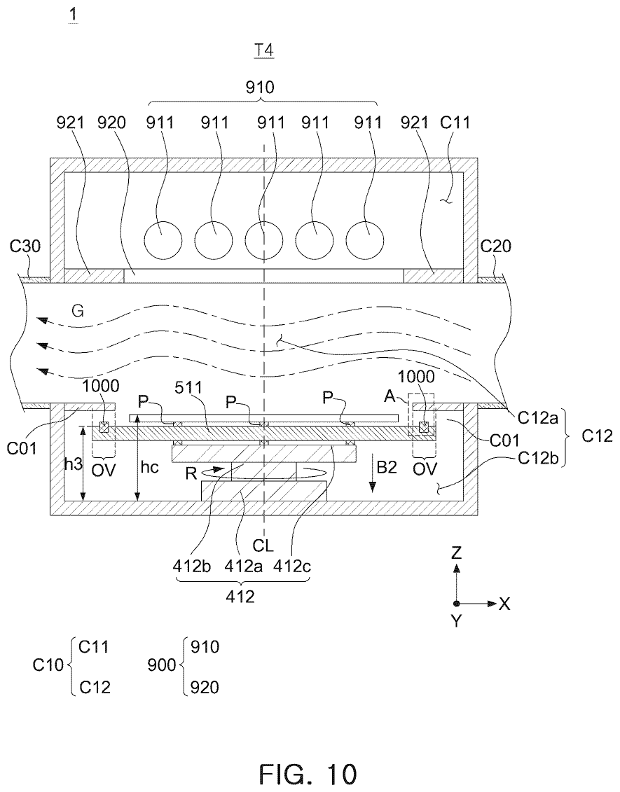

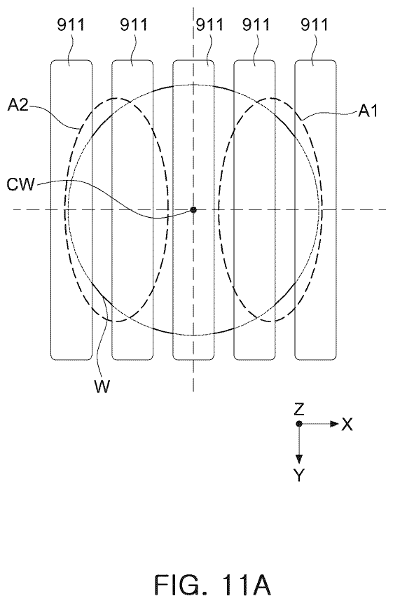

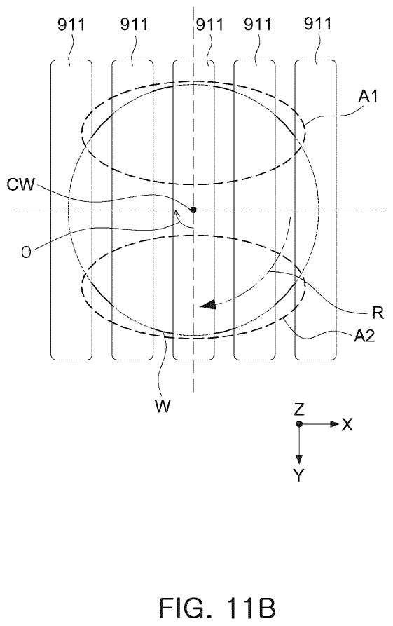

FIG. 10 is a cross-sectional view illustrating a fourth state of a substrate processing apparatus according to an embodiment. FIG. 11A schematically illustrates a top view of a state in which a substrate is disposed during heat treatment. FIG. 11B schematically illustrates a top view of a state in which the substrate of FIG. 11A is rotated at a preset angle and then heat treated.

Referring to FIGS. 10, 11A, and 11B, as described above, when the heat treatment (hereinafter, referred to as the first heat treatment) of the substrate (W) in the third state T3 is completed, the lamp unit 910 may stop emitting light (L). Once the light (L) emission is stopped, the support portion 412 may be lowered to the lower side of the processing position along the second transport direction B2.

In this way, after the first heat treatment of the substrate (W), the lamp unit 910 stops operating, and the state in which the hot plate 511 and the substrate (W) are lowered again by the support portion 412 is defined as the “fourth state T4.” When the substrate processing apparatus 1 enters the fourth state T4, the partition wall portion C01 and the sealing portion 1000 may be separated again by the lowering of the support portion 412. Once the lowering is complete, the substrate (W) may rotate by a preset angle (θ), which will be described in detail below.

For example, in the fourth state T4, the support portion 412 may be lowered to a position between the second state T2 and the third state T3. In this case, when the fourth state T4 is reached, the hot plate 511 may be disposed at a ‘third height h3’ that is higher than the first height h1 described above, but lower than the second height h2. Accordingly, when the fourth state T4 is reached, the substrate (W) may be disposed at an intermediate height (hc) that is higher than the initial height (ha) described above, but lower than the processing height (hb). These heights (for example, the third height h3 and the intermediate height (hc)) may be heights at which the sealing portion 1000 and the partition wall portion C01 are spaced apart from each other by a minimum distance so that the hot plate 511 and the substrate (W) supported thereon may rotate without interference with the partition wall portion C01.

In this way, the hot plate 511 and substrate (W) are not lowered to the height h1, ha in the second state T2, but only lowered to a higher height h3, hc, and then the substrate (W) rotates, thereby not only reducing the time required for the support portion 412 to be lowered, but also reducing power consumption during the lowering operation of the support portion 412.

However, the present disclosure is not limited thereto. As another example, in the fourth state T4, the support portion 412, hot plate 511, and substrate (W) may be lowered to the same position as in the second state T2. For convenience of explanation, the following description will focus on an embodiment in which the hot plate 511 is lowered to the third height h3 in the fourth state T4.

As described above, the hot plate 511 is lowered to the third height h3, and the substrate (W) is also lowered to the intermediate height (hc). Then, the driving shaft 412b may rotate by a preset angle (θ). Consequently, the support plate 412c connected to the upper end of the driving shaft 412b and the hot plate 511 rotate together, thereby rotating the substrate (W) at the preset angle (θ).

As illustrated in FIG. 11A by way of example, when the substrate processing apparatus 1 is in the third state T3, a plurality of lamps 911 may be disposed in a row along the width direction (X) of the processing chamber (C), which is perpendicular to the extension direction (Y), when viewed from above. The substrate (W) is disposed beneath these lamps 911, and light (L) is irradiated to perform the first heat treatment process.

In this case, since multiple lamps 911 are spaced apart from each other by a predetermined distance, a separation space may exist between the lamps 911. Consequently, portions A1 and A2 of the upper surface of the substrate (W) may receive relatively less light (L) than other portions of the upper surface. In this case, the portions A1 and A2 of the upper surface of the substrate (W) may correspond to the areas below the separation spaces formed between the multiple lamps 911.

As described above, this difference in the amount of light (L) irradiation may relatively reduce the amount of ozone gas generated in the area of the first lower space C12a where the portions A1 and A2 of the substrate (W) are located. Consequently, the portions A1 and A2 of the substrate (W) may experience less contact with ozone gas than other portions. Accordingly, the degree of decomposition of the organic film (organic matter) in the aforementioned portions A1 and A2 of the upper surface of the substrate (W) may decrease, resulting in uneven removal of the organic matter from the surface of the substrate (W).

To address this issue, after the first heat treatment is completed, the substrate (W) lowered to the intermediate height (hc) may be rotated at a preset angle (θ) and then reheated (hereinafter, referred to as the second heat treatment).

As illustrated in FIG. 11B by way of example, when the rotation of the substrate (W) at the preset angle (θ) is completed, the positions of portions A1 and A2 of the substrate (W) that received relatively little light (L) during the first heat treatment may be changed. In more detail, the aforementioned portions A1 and A2 of the substrate (W) may be moved to a position corresponding to the lower side of the multiple lamps 911.

For example, the preset angle (θ) may be 90 degrees. In this case, the above-described portions A1 and A2 of the substrate (W) may be rotated 90 degrees and moved downwards of the lamp unit 910 to overlap the lamps 911 as much as possible when viewed from above. However, the present disclosure is not limited thereto, and the preset angle (θ) may be changed based on the specifications of the substrate processing apparatus 1, the shape or size of the substrate (W), the number of heat treatments performed on the substrate (W), or the like.

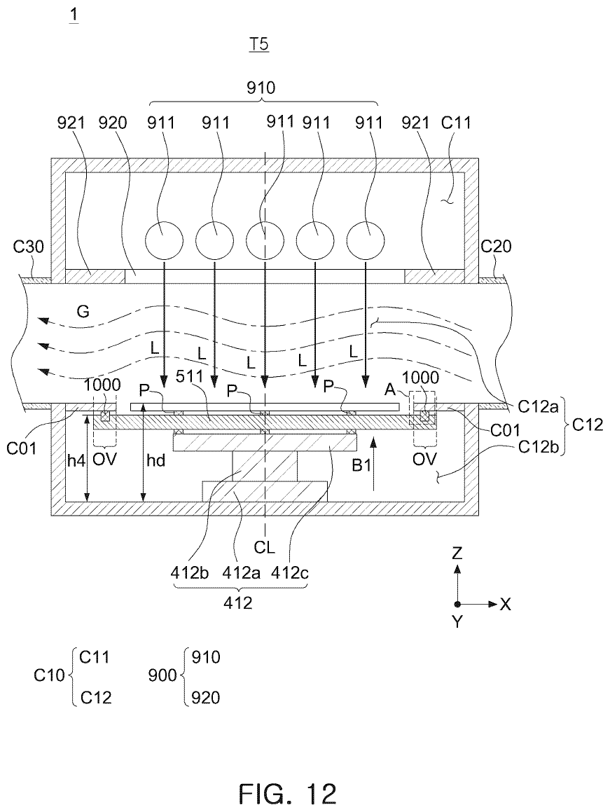

FIG. 12 is a cross-sectional view illustrating a fifth state of the substrate processing apparatus according to an embodiment.

Referring to FIG. 12, when the lowering and rotation of the substrate (W) are completed in the above manner, the support portion 412 may be raised back to the processing position. Accordingly, the hot plate 511 and the substrate (W) supported thereon rise together along the first transport direction B1, so that the space between the first lower space C12a and the second lower space C12b may be sealed again by the sealing portion 1000. In this way, the state in which the substrate (W) rises again while being rotated by a preset angle (θ), and the space between the upper and lower portions of the substrate (W) is resealed is defined as the ‘fifth state T5’.

When the substrate processing apparatus 1 enters the fifth state T5, the substrate (W) may be disposed back into the processing position. At this time, the substrate (W) is rotated by a preset angle (θ) from the third state T3 as described above, and light (L) is again emitted from the lamp unit 910 in this state, thereby performing a reheating treatment (second heat treatment) on the substrate (W). In this fifth state T5, the substrate (W) is rotated by the preset angle (θ) and is then subjected to a second heat treatment, thereby allowing additional decomposition and removal of organic matter on portions A1 and A2 where decomposition of the organic film (organic matter) was relatively insufficient during the first heat treatment.

In this way, by performing heat treatment on the substrate (W) at least twice or more times, rotating the substrate (W) by a predetermined angle (a preset angle) (θ) for each cycle and then reheating, the organic film (organic matter) present on the surface (upper surface) of the substrate (W) may be uniformly removed throughout.

Meanwhile, the substrate processing apparatus 1 may further include a control unit (not illustrated). The control unit may be implemented, for example, in the form of a circuit substrate mounted on the control computer of the substrate processing apparatus 1, a computer chip mounted on the circuit substrate, or software embedded in a computer chip or the control computer.

The control unit is electrically connected to the heating unit 900 and controls the lamp unit 910 to perform heat treatment (or reheat treatment) on the substrate (W). Furthermore, the control unit is electrically connected to the support portion 412 and controls the elevation and/or rotation of the support portion 412. At this time, the detailed method by which the control unit controls the operation of the heating unit 900 and the support portion 412 is the same or similar to that described above, so a detailed description thereof will be omitted.

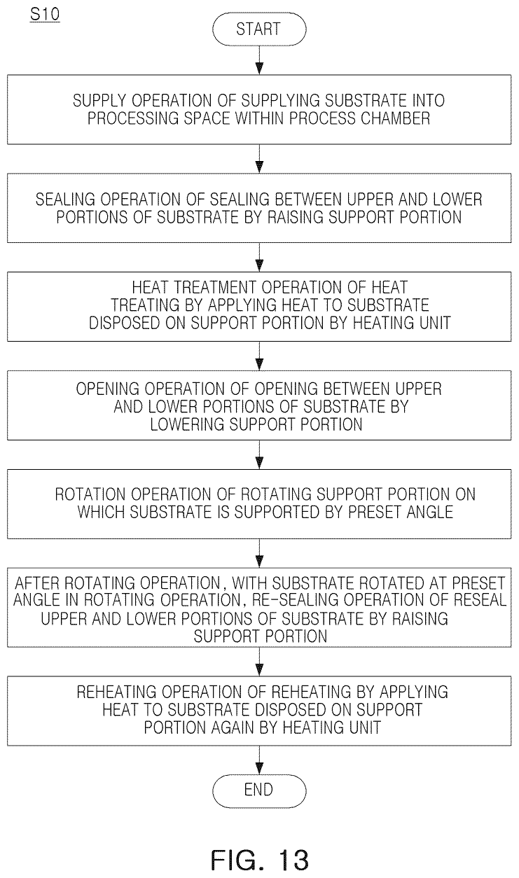

FIG. 13 is a flowchart illustrating a substrate processing method according to an embodiment.

Referring to FIG. 13, a method (hereinafter, “substrate processing method”) (S10) of heat-treating a substrate (W) using the substrate processing apparatus 1 described above may be as follows.

First, a “supply operation” may be performed in which the substrate (W) is supplied to the processing chamber (C).

The substrate (W) may be transported to the processing space C10 via a substrate transport device, such as an application robot 421. Before the substrate (W) is supplied, the substrate processing apparatus 1 may be in a first state T1, as illustrated in FIG. 6 by way of example. In the supply operation, the substrate (W) may be disposed on the hot plate 511 (in more detail, a plurality of support pins (P)) of the substrate processing apparatus 1, which is in the first state T1. Once the supply operation of the substrate (W) is completed, the substrate processing apparatus 1 may enter the second state T2, as illustrated in FIG. 8 by way of example.

Next, a “sealing operation” may be performed, in which the support portion 412 is raised to seal the space between the upper and lower portions of the substrate (W).

In the sealing operation, the hot plate 511 may be raised in the first transport direction B1 by the support portion 412 while the substrate (W) is supported on the upper portion thereof. The support portion 412 may raise the hot plate 511 until the upper portion of the sealing portion 1000 is in close contact with the lower surface of the partition wall portion C01. Accordingly, the first lower space C12a and the second lower space C12b may be separated from each other by being sealed by the sealing portion 1000. Thus, during the sealing operation, as illustrated in FIG. 9 by way of example, the substrate processing apparatus 1 may enter a third state T3 in which the first lower space C12a and the second lower space C12b are sealed and separated by the sealing portion 1000.

Next, a “heat treatment operation” may be performed, in which the substrate (W) disposed on the support portion 412 is heated and processed by the heating unit 900.

Referring back to FIG. 9, in the heat treatment operation (hereinafter, the first heat treatment operation), the substrate (W) is disposed at the processing position, and the lamp unit 910 may begin to emit light (L) while the space between the first lower space C12a and the second lower space C12b is sealed. At this time, the emitted light (L) may pass through the window 920 and enter the first lower space C12a, and may then meet with gas (process gas) to generate ozone gas. The ozone gas may contact the upper surface of the substrate (W) within the first lower space C12a and decompose organic substances present on the substrate (W). At this time, the decomposition products generated by the decomposition of the organic substances may be discharged to the gas discharge portion C30 along the airflow formed within the first lower space C12a.

Next, an ‘opening operation’ may be performed in which the support portion 412 is lowered to open the space between the upper and lower portions of the substrate (W).

Once the first heat treatment operation is completed, the support portion 412 may be lowered along the second transport direction B2. During the opening operation, as illustrated in FIG. 10 by way of example, the support portion 412 may be lowered to be lower than the processing position. Furthermore, the hot plate 511 and the substrate (W) supported thereon are also lowered, thereby allowing the sealing portion 1000 to be spaced apart from the lower surface of the partition wall portion C01. This separation of the substrate (W) and the hot plate 511 from the partition wall portion C01 secures the space necessary for the hot plate 511 to rotate.

Next, a “rotation operation” may be performed, in which the support portion 412 is rotated at a preset angle (θ) to rotate the substrate (W).

Referring again to FIG. 10, in the rotation operation, the driving shaft 412b rotates due to the driving force provided by the drive motor 412a, thereby rotating the hot plate 511 connected to the driving shaft 412b. At this time, the hot plate 511 may rotate around the driving shaft 412b by a preset angle (θ).

Next, after the rotation operation is completed, the support portion 412 is raised while the substrate (W) is rotated by the preset angle (θ), thereby resealing the space between the upper and lower portions of the substrate (W), in a “resealing operation.”

In the resealing operation, as illustrated in FIG. 12 by way of example, the support portion 412 may be raised back to the processing position. In addition, the hot plate 511 and the substrate (W) supported thereon also rise along the first transport direction B1, allowing the upper end of the sealing portion 1000 to once again contact the lower surface of the partition wall portion C01. Consequently, the first lower space C12a and the second lower space C12b may be separated from each other by sealing the space therebetween again.

Next, after the resealing operation is completed, a “reheating operation” may be performed, in which the heating unit 900 reheats and processes the substrate (W) disposed on the support portion 412.

Referring again to FIG. 12, in the reheating operation, a second heat treatment may be performed on the substrate (W) disposed in a state of being rotated at a preset angle (θ) in the aforementioned rotation operation. By performing this second heat treatment, the entire surface (upper surface) of the substrate (W) may be uniformly contacted with the gas (G) containing ozone gas, thereby obtaining uniform decomposition of organic matter.

Furthermore, the substrate processing method (S10) described above may further include an exhaust operation. In the exhaust operation, new gas (process gas) is introduced into the processing space C10 (the first lower space C12a) through the gas inlet portion C20, and the gas within the processing space C10 (the first lower space C12a) may be discharged through the gas discharge portion C30. This creates an airflow within the processing space C10 that flows from the gas inlet portion C20 toward the gas discharge portion C30.

Referring again to FIGS. 6, 8 to 10, and 12, the exhaust operation may be performed continuously throughout the entire process of the substrate processing method (S10). For example, the exhaust operation may be performed continuously, starting with the aforementioned supply operation and continuing sequentially up to the reheating operation. This allows for the exhaust of foreign substances, such as dust and fumes, present within the processing space C10 before and after the substrate (W) supply operation, thereby reducing the occurrence of substrate (W) defects.

Furthermore, during the heat treatment and reheating operations for the substrate (W), the air current formed within the processing space C10 may ensure that the gas (G) containing ozone gas evenly contacts the upper surface of the substrate (W). Furthermore, the air current formed within the processing space C10 continuously exhausts the reaction products CO₂, and H₂0 generated during the heat treatment and reheating processes, thereby preventing the reaction products from settling on the surface of the substrate (W) and causing defects.

Then, when the decomposition and removal of the organic film (organic matter) existing on the upper surface of the substrate (W) is completed through the heat treatment process (heat treatment operation, reheat treatment operation) for the substrate, the substrate (W) may be transferred to the outside of the processing chamber (C) again by the application robot 421. Afterwards, after a new substrate (W) is supplied into the processing chamber (C), the substrate processing method (S10) described above may be performed operation by operation. By repeating this method, processing may be performed on a plurality of substrates (W).

Meanwhile, after the heat treatment operation, the opening operation, rotation operation, resealing operation, and reheating operation may be performed at least once for each substrate (W). For example, when processing a single substrate (W), the opening operation, rotation operation, resealing operation, and reheating operation may be performed once each after the heat treatment operation, thereby completing the substrate processing process. In another example, when processing a single substrate (W), the opening operation, rotation operation, resealing operation, and reheating operation may be repeated at least twice or more times after the heat treatment operation, thereby completing the substrate processing process.

The substrate processing apparatus 1 and the substrate processing method (S10) according to embodiments, as described above, may uniformly irradiate light (L) across the entire upper surface of the substrate (W) supplied into the processing chamber (C), thereby effectively and uniformly removing organic substances present on the surface of the substrate (W).

In the above examples, the substrate processing apparatus in the present disclosure has been described as an embodiment applied to a photolithography process, but the present disclosure is not limited thereto, and it is obvious to those skilled in the art that the present disclosure may be applied to various processes such as substrate etching processes, testing, and packaging processes, and this also falls within the scope of the present disclosure.

As set forth above, a substrate processing apparatus and a substrate processing method according to embodiments may uniformly irradiate light to the entire surface of a substrate supplied into a processing chamber, thereby effectively and uniformly removing organic substances present on the substrate surface.

While example embodiments have been illustrated and described above, it will be apparent to those skilled in the art that modifications and variations could be made without departing from the scope of the present disclosure as defined by the appended claims.

1. A substrate processing apparatus comprising:
a processing chamber having a processing space provided therein;
a support portion disposed within the processing space, capable of being raised and lowered and rotatable, and including a hot plate configured to support and heat a substrate; and
a heating unit disposed within the processing space to be spaced apart from an upper side of the support portion, and including a lamp unit containing a plurality of lamps configured to heat the substrate,
wherein the processing chamber includes,
a gas inlet portion for introducing gas into the processing space;
a gas discharge portion spaced apart from the gas inlet portion and configured to discharge the gas from the processing space; and
a sealing portion disposed below the gas inlet portion or the gas discharge portion, and selectively sealing between an upper portion and a lower portion of the substrate when the substrate is seated on the support portion.

2. The substrate processing apparatus of claim 1, wherein the processing space includes,
an upper space in which the lamp unit is disposed, and a lower space which is separated from the upper space and in which the substrate is disposed and a processing process for the substrate is performed, and
the heating unit further includes a window disposed between the upper space and the lower space.

3. The substrate processing apparatus of claim 1, wherein the gas inlet portion is disposed on one side of the substrate, and
the gas discharge portion is disposed on the other side of the substrate and faces the gas inlet portion along a width direction of the processing chamber.

4. The substrate processing apparatus of claim 3, wherein the processing chamber further includes a partition wall portion protruding from an inner side surface of the processing chamber into the processing space toward the substrate or the support portion.

5. The substrate processing apparatus of claim 4, wherein the partition wall portion is disposed to partially overlap an edge portion of the hot plate when viewed from above, and extends along a circumferential direction of the substrate on which the hot plate is supported, and
the sealing portion selectively seals a space between the partition wall portion and the hot plate by raising or lowering the support portion.

6. The substrate processing apparatus of claim 5, wherein the hot plate includes a coupling groove formed concavely inwardly from an upper surface of the hot plate and positioned on the edge portion, and
the sealing portion is disposed such that a lower end portion of the sealing portion is inserted into the coupling groove and an upper end portion of the sealing portion protrudes upwardly of the coupling groove.

7. The substrate processing apparatus of claim 6, wherein the sealing portion includes an extension portion extending inwardly in the radial direction of the hot plate from the lower end portion and inserted and positioned within the coupling groove.

8. The substrate processing apparatus of claim 1, wherein the sealing portion includes an inner groove therein.

9. The substrate processing apparatus of claim 1, wherein the sealing portion is detachably coupled to the hot plate.

10. The substrate processing apparatus of claim 1, further comprising a control unit controlling the lamp unit to heat the substrate and controlling raising and lowering of the support portion to seal or open between the upper and lower portions of the substrate.

11. The substrate processing apparatus of claim 10, wherein the control unit is configured to raise the support portion when the heating unit heats the substrate, to seal between the upper and lower portions of the substrate by the sealing portion.

12. The substrate processing apparatus of claim 11, wherein the control unit is configured to lower the support portion to open between the upper and lower portions of the substrate when a heating treatment for the substrate is completed.

13. The substrate processing apparatus of claim 12, wherein the control unit is configured to control the support portion to rotate by a preset angle when the support portion is lowered, and then to control the sealing portion to seal between the upper and lower portions of the substrate again by raising the support portion.

14.-19. (canceled)

20. A substrate processing apparatus comprising:
a processing chamber having a processing space provided therein;
a support portion disposed within the processing space, capable of being raised and lowered and rotatable, and including a hot plate configured to support and heat a substrate; and
a heating unit disposed within the processing space, while being spaced apart from an upper side of the support portion, and including a lamp unit including a plurality of lamps configured to heat the substrate,
wherein the processing chamber includes,
a gas inlet portion disposed on one side wall of the processing chamber, and allowing gas to be introduced into the processing space therethrough;
a gas discharge portion disposed on the other side wall of the processing chamber, facing the gas inlet portion, spaced apart from the gas inlet portion, and discharging the gas from the processing space therethrough; and
a sealing portion disposed below the gas inlet portion or the gas discharge portion, and selectively sealing between an upper portion and
a lower portion of the substrate when the substrate is seated on the support portion, the processing space includes an upper space in which the lamp unit is disposed, and a lower space which is separated from the upper space and in which the substrate is disposed and a processing process for the substrate is performed,
wherein the lower space includes a first lower space, and a second lower space, disposed below the first lower space, and separated from or communicating with the first lower space by the sealing portion,
the processing chamber further includes a partition wall portion protruding from an inner side surface of the processing chamber into the processing space toward the substrate or the support portion,
wherein the partition wall portion is disposed to partially overlap an edge portion of the hot plate when viewed from above, and extends in a circumferential direction of the substrate supported on the hot plate,
the sealing portion selectively seals between the partition wall portion and the hot plate by raising and lowering the support portion,
the hot plate includes a coupling groove disposed in the edge portion, concave inwardly from an upper surface of the hot plate and extending in the circumferential direction of the hot plate,
the sealing portion has a ring shape extending in the circumferential direction of the hot plate, with a lower end portion inserted into the coupling groove and an upper end portion protruding upwardly from the coupling groove and in contact with a lower surface of the partition wall portion by raising of the support portion, and selectively seals between the first lower space and the second lower space by being vertically pressurized between the hot plate and the partition wall portion, the support portion rises and the first lower space and the second lower space are sealed by the sealing portion, when the heating unit heats the substrate, and
the support portion is lowered and opens between the first lower space and the second lower space, when a heating process for the substrate is completed.
